(19) United States
(12) Patent Application Publication
(10) Pub. No.: US 2026/0253852 A1
(43) Pub. Date: Aug. 27, 2026

(54) NON-CONTACT PLASMA MONITORING METHOD AND NON-CONTACT PLASMA MONITORING DEVICE USING SAME

(71) Applicant: KOREA INSTITUTE OF FUSION ENERGY, Daejeon (KR)

(72) Inventors: Dae Chul KIM, Gunsan-si (KR); Young Woo KIM, Hwaseong-si (KR); Jong Sik KIM, Gunsan-si (KR); Yong Hyun KIM, Gunsan-si (KR); Jung Sik YOON, Daejeon (KR); Jong Bae PARK, Gunsan-si (KR); Jong Hyun SHIN, Gunsan-si (KR)

(73) Assignee: KOREA INSTITUTE OF FUSION ENERGY, Daejeon (KR)

(21) Appl. No.: 18/992,264

(22) PCT Filed: May 30, 2023
(86) PCT No.: PCT/KR2023/007347

§ 371 Date: Jan. 8, 2025

(30) Foreign Application Priority Data
Jul. 8, 2022 (KR) 10-2022-0084493

(51) Int. Cl. H01J 37/32

(52) U.S. Cl. CPC H01J 37/32935; H01J 37/3211

(57) ABSTRACT

A non-contact plasma monitoring method and a non-contact plasma monitoring device using same are disclosed. The non-contact plasma monitoring method may comprise: a first step of arranging one or more RF sensors on the outside of an inductively coupled plasma generator including an antenna, and measuring, as a function of time, induced electromotive force induced to each of the RF sensors by means of the antenna; a second step of performing the Fourier transform on the function of induced electromotive force at individual times, and then deriving the amplitude value of each of n-th harmonics; and a third step of deriving the state of plasma within the plasma generator from the amplitude values of each of the n-th harmonics.

### BACKGROUND

### Field of the Disclosure

The present disclosure relates to a contactless plasma monitoring method and a contactless plasma monitoring device using the same.

### Description of Related Art

In an operation of a plasma generator, in order to measure a plasma state such as electron density or electron temperature of a plasma, a method of directly installing a diagnostic device in a plasma reactor is used. In this case, contamination on the diagnostic device may occur depending on the process conditions. In addition, when the diagnostic device is applied while the process is in progress, there is a possibility that the stability of the process is deteriorated and impurities are introduced. Accordingly, there is a need for a method of measuring a plasma state using a device outside the plasma generator.

### SUMMARY OF THE INVENTION

A purpose of the present disclosure is to provide a non-contact plasma monitoring method capable of measuring a plasma state using a diagnostic device outside the plasma reactor without installing the diagnostic device inside the plasma reactor.

Another purpose of the present disclosure is to provide a contactless plasma monitoring device implementing the contactless plasma monitoring method.

In one aspect, the present disclosure provides a contactless plasma monitoring method comprising: a first step of positioning one or more RF sensors outside an ICP (Inductively Coupled Plasma) generator including an antenna, and of measuring an induced electromotive force induced in the RF sensor by the antenna as a function based on a time; a second step of performing a Fourier transform on the function based on the time of the induced electromotive force and derive an amplitude value of an n-th harmonic from the Fourier transform result; and a third step of deriving a state of plasma in the plasma generator based on the amplitude value of the n-th harmonic, wherein n is a natural number of 1 or larger.

Through the above steps, the contactless plasma monitoring method of the present disclosure may monitor the plasma state using the monitoring means disposed outside the plasma generator.

In one embodiment of the contactless plasma monitoring method, the antenna may be formed on at least one plane of the inductively coupled plasma generator. In one embodiment, the antenna may be formed on an upper plane of the inductively coupled plasma generator. In an embodiment, the antenna may be formed in a spiral shape while being disposed on an upper plane of the inductively coupled plasma generator. In an embodiment, each of the RF sensors may be disposed outside the antenna. In an embodiment, each RF sensor may be oriented such that a plane defined by each RF sensor is perpendicular to a plane defined by the antenna. In an embodiment, each RF sensor may be oriented such that a plane defined by each RF sensor is perpendicular to a plane in which the spiral-shaped antenna is formed.

The RF sensor is positioned and oriented as described above such that the induced electromotive force may be induced in the RF sensor under the current applied to the antenna.

In one embodiment of the contactless plasma monitoring method, n is 1, wherein in the third step, a linear proportional relationship between the plasma electron density directly measured inside the plasma generator and the amplitude value is derived, and then an unknown plasma electron density is derived from an amplitude value measurement result based on the linear proportional relationship.

In one embodiment of the contactless plasma monitoring method, two or more RF sensors may be disposed in the first step. In an embodiment, the antenna may be formed in a spiral shape while being disposed on an upper plane of the inductively coupled plasma generator. In an embodiment, two or more of the RF sensors may be positioned so that radial distances thereof to the spiral formed by the antenna are different from each other. In an embodiment, in the first step, in the third step, a distribution of unknown plasma electron density is derived based on a deriving result of the plasma electron density from each of the RF sensors.

In one embodiment, each RF sensor may be positioned on top of the antenna.

In one embodiment of the contactless plasma monitoring method, the third step includes determining whether impurities are introduced into the plasma, based on whether the amplitude value of the n-th harmonic is changed by a predetermined value or greater. In one embodiment of the contactless plasma monitoring method, n is 5 or 6.

In another aspect, the present disclosure provides a contactless plasma monitoring device comprising: a sensor unit including: at least one RF sensor; and a recording unit configured to measure an induced electromotive force induced in each of the RF sensors and record the measured induced electromotive force as a function based on a time; and a monitor unit including: a computation unit configured to perform the Fourier transform on the recorded function based on the time of the induced electromotive force; and an output unit configured to derive a plasma state from an amplitude value of an n-th harmonic based on the Fourier-transform result of the computation unit, wherein n is a natural number of 1 or greater.

The device as described above may secure plasma stability by monitoring the state of plasma while being disposed outside the plasma generator.

In an embodiment, the contactless plasma monitoring device may monitor plasma in an inductively coupled plasma generator in which an antenna is formed on at least one plane of the generator. In an embodiment, the contactless plasma monitoring device may monitor plasma in an inductively coupled plasma generator in which an antenna is formed on an upper plane of the generator. In an embodiment, the contactless plasma monitoring device may monitor plasma in an inductively coupled plasma generator in which a spiral-shaped antenna is formed on an upper plane of the generator. In one embodiment, each RF sensor may be formed to be disposed outside the antenna. In an embodiment, each of the RF sensors may be oriented such that a plane defined by each of the RF sensors is perpendicular to a plane defined by the antenna. In an embodiment, each of the RF sensors may be oriented such that a plane defined by each of the RF sensors is perpendicular to a plane in which the spiral-shaped antenna is formed.

The RF sensor is positioned and oriented as described above such that the induced electromotive force may be induced in the RF sensor under the current applied to the antenna.

In one embodiment of the contactless plasma monitoring device, n is 1, wherein the output unit is configured to derives a linear proportional relationship between a plasma electron density directly measured inside the plasma generator and the amplitude value, and then to derive an unknown plasma electron density from an amplitude value measurement result based on the linear proportional relationship.

In an embodiment, the sensor unit may include two or more RF sensors. In an embodiment, the antenna may be formed in a spiral shape while being disposed on an upper plane of the inductively coupled plasma generator. In an embodiment, two or more of the RF sensors may be positioned such that radial distances thereof to the spiral formed by the antenna are different from each other. In one embodiment, the output unit is configured to by derive the plasma electron density from each of the RF sensors and to derive an unknown plasma electron density distribution based on the derived plasma electron density.

In an embodiment, one or more of the RF sensors may be positioned on top of the antenna.

In one embodiment of the contactless plasma monitoring device, the output unit is configured to determine whether impurities are introduced into the plasma, based on whether the amplitude value of the n-th harmonic is changed by a predetermined value or greater. In one embodiment of the contactless plasma monitoring device, n is 5 or 6,

The contactless plasma monitoring device according to an embodiment of the present disclosure may monitor a plasma state including plasma electron density and impurities using the device outside the plasma, thereby securing stability of the plasma.

The contactless plasma monitoring device according to an embodiment of the present disclosure may implement the contactless plasma monitoring method to monitor a plasma state while maintaining the stability of the plasma.

### BRIEF DESCRIPTION OF THE DRAWINGS

FIG. 1 is a flowchart illustrating a non-contact plasma monitoring method according to an embodiment of the present disclosure.

FIG. 2 illustrates a configuration of a contactless plasma monitoring device according to an embodiment of the present disclosure.

FIG. 3 is a diagram illustrating an embodiment of a scheme of positioning a plurality of RF sensors when the contactless plasma monitoring device according to an embodiment of the present disclosure includes two or more RF sensors.

FIGS. 4 to 9 are graphs showing results according to experimental examples of the present disclosure.

### DETAILED DESCRIPTION OF THE INVENTION

Hereinafter, embodiments of the present disclosure will be described in detail with reference to the accompanying drawings. The present disclosure may be subjected to various changes and may have various forms. Thus, particular embodiments will be illustrated in the drawings and will be described in detail herein. However, this is not intended to limit the present disclosure to a specific disclosed form. It should be understood that the present disclosure includes all modifications, equivalents, and replacements included in the spirit and technical scope of the present disclosure. While describing the drawings, similar reference numerals are used for similar components. In the accompanying drawings, the dimensions of the structures are shown in an enlarged view for clarity of the present disclosure.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “including”, “include”, and “including” when used in this specification, specify the presence of the stated features, integers, operations, elements, and/or components, but do not preclude the presence or addition of one or more other features, integers, operations, elements, components, and/or portions thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

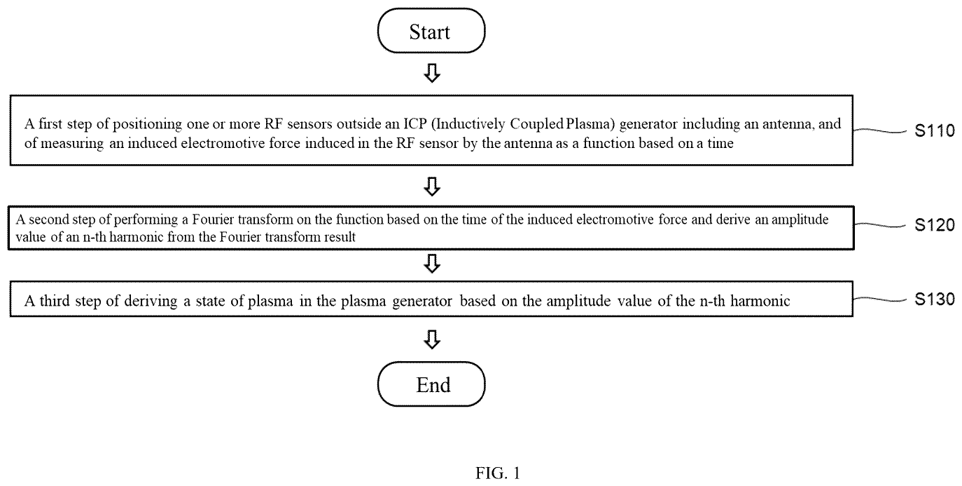

FIG. 1 is a flowchart illustrating a non-contact plasma monitoring method according to an embodiment of the present disclosure.

Referring to FIG. 1, the contactless plasma monitoring method according to an embodiment of the present disclosure includes a first step S110 of positioning one or more RF sensors outside an ICP (Inductively Coupled Plasma) generator including an antenna, and of measuring an induced electromotive force induced in the RF sensor by the antenna as a function based on a time; a second step S120 of performing a Fourier transform on the function based on the time of the induced electromotive force and derive an amplitude value of an n-th harmonic from the Fourier transform result; and a third step S130 of deriving a state of plasma in the plasma generator based on the amplitude value of the n-th harmonic, wherein n is a natural number of 1 or larger. Through the above steps, the contactless plasma monitoring method of the present disclosure may monitor the plasma state using the device outside the plasma generator.

The first step S110 is a step of measuring the induced electromotive force generated from the plasma generator, and in particular, the induced electromotive force is measured as a function based on the time. The plasma generator, particularly, an inductively coupled plasma generator, may include an antenna, and may generate plasma inside the plasma generator through change in the current applied to the antenna, such that a change in a surrounding magnetic field around the antenna may occur. Thus, when the RF sensor is positioned around the antenna, the induced electromotive force may be induced in the RF sensor under the change in the magnetic field. Therefore, the RF sensor may be positioned and oriented such that the induced electromotive force may be induced therein under the change in the currented applied to the antenna. In one embodiment, the antenna may be formed on at least one plane of the inductively coupled plasma generator. In one embodiment, the antenna may be formed on one upper plane of the inductively coupled plasma generator. In an embodiment, the antenna may be formed in a spiral shape while being formed on one upper plane of the inductively coupled plasma generator. In an embodiment, each of the RF sensors may be positioned outside the antenna. In an embodiment, each RF sensor may be oriented such that a plane defined by each RF sensor is perpendicular to a plane defined by the antenna. In an embodiment, each RF sensor may be oriented such that the plane defined by each RF sensor is perpendicular to a plane in which the spiral-shaped antenna is formed. The position and orientation of the RF sensor as described above may allow the induced electromotive force to be induced in the RF sensor under the change in the current applied to the antenna.

The second step S120 is a process of performing the Fourier transform on the function based on the time of the induced electromotive force. As is known in the art, the Fourier transform may decompose the function based on the time into frequency components which may be numbered in an order of the fundamental frequency component as the first harmonic, the second harmonic, . . . , n-th harmonic. That is, in the context of the present specification, the harmonic is a result of Fourier transform, and the n-th harmonic means the n-th component harmonic wave in the order of the frequency components as a result of the Fourier transform. The amplitude value of the n-th harmonic means the amplitude value of the n-th harmonic wave. In the second step S120, the Fourier transform is performed on the function based on the time of the induced electromotive force to obtain the frequency components, and the amplitude value of each of the frequency components or a specific n-th harmonic is derived.

The third step S130 is a step in which information on the plasma state may be derived based on the amplitude value derived in the second step S120. The second step S120 derives the amplitude value of the n-th harmonic. In this regard, it may be determined, based on the n value, how close the n-th harmonic is to the fundamental frequency component of the function based on the time of the induced electromotive force. Accordingly, the contactless plasma monitoring method according to an embodiment of the present disclosure may derive a specific plasma state using the combination of the second step S120 and the third step S130.

In an embodiment, n may be 1, and in the third step S130, a linear proportional relationship between the plasma electron density directly measured inside the plasma generator and the amplitude value may be derived, and then an unknown plasma electron density may be derived from the amplitude value measurement result based on the linear proportional relationship. The scheme of directly measuring the plasma electron density using the device inside the plasma generator may be measurement using a probe. The scheme of directly measuring the plasma electron density using the measuring means inside the plasma generator as described above is a conventional technology, and has a disadvantage in that the measuring means affects the plasma electron density. The contactless plasma monitoring method according to an embodiment of the present disclosure is based on the discovery that the plasma electron density measured in the prior art as described above and the amplitude value of the first harmonic of the Fourier transform result of the function based on the time of the induced electromotive force derived in the second step S120 and the third step S130 has a linear proportional relationship. In an embodiment, the non-contact plasma monitoring method according to an embodiment of the present disclosure may be calibrated based on the conventional direct measurement method.

The above method is related to the relative positional relationship between the RF sensor and the antenna and the electron density of the point to be measured. Therefore, when two or more RF sensors are used, plasma electron density may be measured at a plurality of points. Thus, the unknown electron density distribution may be measured. In an embodiment, two or more RF sensors may be positioned in the first step S110. In an embodiment, two or more of the RF sensors may be positioned so that radial distances thereof to the spiral formed by the antenna are different from each other. In an embodiment, in the third step S130, a distribution of unknown plasma electron density may be derived by deriving plasma the electron density from each of the RF sensors.

The RF sensor is not particularly limited as long as it is positioned around the antenna, particularly on top of of the antenna such that the induced electromotive force is induced therein. In an embodiment, each of the RF sensors may be positioned on top of the antenna.

The measurement of the electron density of the plasma or the electron density distribution of the plasma as described above is only an example of the plasma state that may be derived using the contactless plasma monitoring method according to an embodiment of the present disclosure. As long as the correlation thereof with another plasma state measured by the prior art may be derived through the above method, the type of the plasma state is not particularly limited.

In an embodiment, in the third step S130, whether impurities are introduced into the plasma may be identified based on whether the change in amplitude value of the n-th harmonic is equal to or greater than a predetermined value. In an embodiment, n may be 5 or 6.

As described above, the contactless plasma monitoring device according to the embodiment of the present disclosure may monitor the plasma state including the plasma electron density and the impurities while being positioned outside the plasma, such that stability of the plasma may be secured.

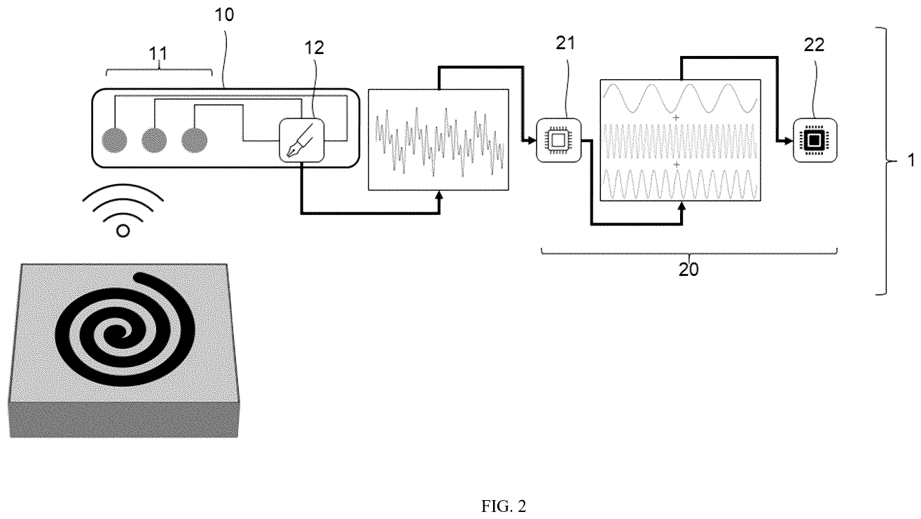

FIG. 2 illustrates a configuration of a contactless plasma monitoring device according to an embodiment of the present disclosure.

Referring to FIG. 2, the contactless plasma monitoring device 1 according to an embodiment of the present disclosure includes: a sensor unit 110 including one or more RF sensors 11; and a recording unit 12 capable of measuring the induced electromotive force induced in each RF sensor 11 and recording the measured induced electromotive force as the function based on the time therein; and a monitor unit 20 including a computation unit 21 capable of performing the Fourier transform on the recorded function based on the time of the induced electromotive force; and an output unit 22 for deriving a plasma state based on the amplitude value of the n-th harmonic from the result of Fourier formation using the computation unit 21. In this regard, n may be a natural number equal to or greater than 1. The above-described device may secure the plasma stability by monitoring the state of the plasma while being positioned outside the plasma generator.

The contactless plasma monitoring device according to an embodiment of the present disclosure is an embodiment of a device capable of implementing the contactless plasma monitoring method as described above. Thus, the description of the terms identical or similar to the terms used in the detailed description of the contactless plasma monitoring method as described above may be identically or similarly applied to the same or similar terms of the contactless plasma monitoring device according to an embodiment of the present disclosure.

The RF sensor 11 has the induced electromotive force induced therein under the current applied to the plasma generator or some components of the plasma generator. In the context of the present specification, the RF sensor is a device capable of sensing a signal having a radio frequency (RF), and may include, for example, a coil. In the context of the present specification, a coil is a wire member in which the wire defines at least one closed surface. The electromotive force is induced therein so that a current may flow through the wire when the change in the magnetic field passing through the closed surface formed by the wire occurs.

One or more RF sensors 11 may be provided. In one embodiment, one RF sensor 11 may be provided. In another embodiment, more than one RF sensor 11 may be provided.

The recording unit 12 is a device capable of measuring and recording the induced electromotive force induced in the RF sensor 11. The induced electromotive force may be recorded as the function based on the time, and thus the recording unit 12 may further include a separate storage device. In one embodiment, the recording unit 12 may directly measure the induced electromotive force. In another embodiment, the recording unit 12 may measure a physical quantity such as a current rather than the induced electromotive force and calculate the electromotive force based on the measurement. In this case, the recording unit 12 may further include a separate calculation device.

The computation unit 21 may perform Fourier transform on the function based on the time of the induced electromotive force as measured by and recorded in the recording unit 12 to obtain the component frequencies, and derive an amplitude value of each frequency component. In an embodiment, the computation unit 21 may derive an amplitude value of an n-th harmonic from the result of the Fourier transform.

The output unit 22 may derive a plasma state based on the information on the component frequency derived by the computation unit 21, especially, based on the amplitude value of the n-th harmonic. In an embodiment, the scheme of deriving the plasma state using the output unit 22 may include deriving the plasma state via calibration based on the linear correlation between the specific plasma state measured by the conventional technology and the component frequency derived by the computation unit 21, in particular, the amplitude value of the n-th harmonic.

Referring to FIG. 2, the computation unit 21 and the output unit 22 are illustrated as separate members. However, this is merely an example, and is to describe the functions thereof. As long as the purpose of the present disclosure may be achieved and all functions of the computation unit 21 and the output unit 22 may be performed, the computation unit 21 and the output unit 22 may be integrated into one member. In an embodiment, the computation unit 21 and the output unit 22 may be integrated into one computing device.

Referring to FIG. 2, the recording unit 12 and the monitor unit 20 are illustrated as separate members. However, this is merely an example, and is to describe the functions thereof. As long as the purpose of the present disclosure may be achieved and all functions of the recording unit 12 and the monitor unit 20 may be performed, the recording unit 12 and the monitor unit 20 may be integrated into one member. In one embodiment, the recording unit 12 and the monitor unit 20 may be integrated into one computing device.

Referring to FIG. 2, the contactless plasma monitoring device may monitor plasma in the inductively coupled plasma generator. In an embodiment, the contactless plasma monitoring device may monitor plasma in the inductively coupled plasma generator, wherein the antenna is formed on at least one plane of the inductively coupled plasma generator. In an embodiment, the contactless plasma monitoring device may monitor plasma in the inductively coupled plasma generator in which the antenna is formed on top of an upper plane of the generator. In an embodiment, the contactless plasma monitoring device may monitor plasma in the inductively coupled plasma generator in which an antenna having a spiral shape is formed on top of an upper plane of the generator. In FIG. 2, the shape of the antenna is illustrated as a spiral shape, but this is merely an example, and the shape of the antenna is not particularly limited. Although the inductively coupled plasma generator and/or the antenna of the inductively coupled plasma generator are not included in or integrated with the contactless plasma monitoring device according to the embodiment of the present disclosure, the contactless plasma monitoring device according to the embodiment of the present disclosure and/or the RF sensor 11 included in the device may be positioned and oriented so as to be optimized for measuring the plasma state of a general inductively coupled plasma generator and/or a specific inductively coupled plasma generator. In one embodiment, each RF sensor may be formed to be positioned outside the antenna. In an embodiment, each of the RF sensors may be formed such that a plane defined by each of the RF sensors is perpendicular to a plane defined by the antenna. In an embodiment, each of the RF sensors 11 may be formed such that a plane defined by each of the RF sensors is perpendicular to a plane in which the spiral-shaped antenna is formed. The RF sensor may be positioned and oriented as described above such that the induced electromotive force may be induced in the RF sensor of the device under the change applied to the antenna.

The information on the component frequency output from the computation unit 21 after the Fourier transform using the computation unit 21 or the plasma state derived using the output unit 22 is not particularly limited as long as the correlation therebetween may be derived. In an embodiment, n is 1, that is, the information on the component frequency derived by the computation unit 21 is the amplitude value of the first harmonic, and the output unit 22 may derive the linear proportional relationship between the plasma electron density directly measured inside the plasma generator and the amplitude value, and then derive an unknown plasma electron density from the amplitude value measurement result based on the linear proportional relationship. In an embodiment, the contactless plasma monitoring device according to an embodiment of the present disclosure may be pre-calibrated based on a value derived by a conventional plasma insertion device including the probe scheme.

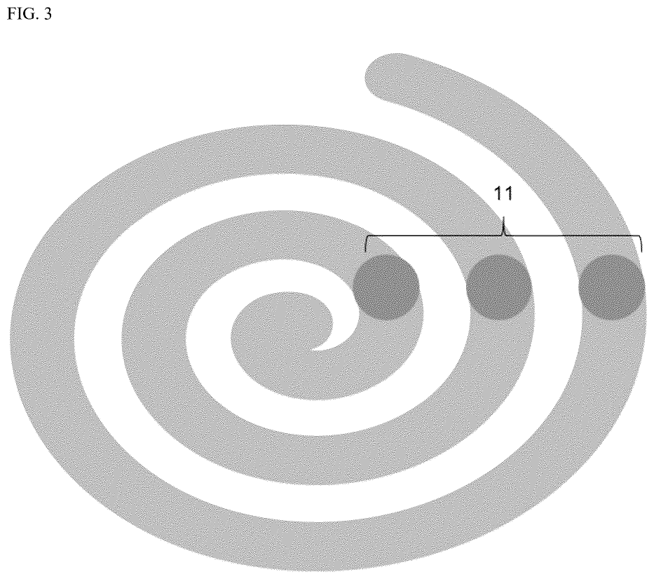

Referring to FIG. 2 continuously, in an embodiment, the sensor unit 10 may include two or more RF sensors 11. FIG. 3 is a diagram illustrating an embodiment of a scheme of positioning a plurality of RF sensors when the contactless plasma monitoring device according to an embodiment of the present disclosure includes two or more RF sensors. Referring to FIG. 3 together with FIG. 2, in an embodiment, two or more of the RF sensors 11 may be positioned such that radial distances thereof to the spiral formed by the antenna are different from each other. Further, in this case, in an embodiment, the output unit may derive a distribution of unknown plasma electron density by deriving the plasma electron density from each of the RF sensors.

Referring to FIG. 3 continuously, in an embodiment, one or more of the RF sensors may be positioned on top of the antenna.

Referring to FIG. 2 continuously, in another embodiment, the computation unit 21 may derive amplitude values of a plurality of harmonics, and the output unit 22 may derive plasma-related information other than plasma electron density or distribution of plasma electron density, based on the derived amplitude values of the plurality of harmonics. In an embodiment, the output unit 22 may determine whether impurities are introduced into the plasma based on whether the change in the amplitude value of the n-th harmonic is greater than or equal to the predetermined value. In an embodiment, n may be 5 or 6.

As described above, the contactless plasma monitoring device according to an embodiment of the present disclosure may implement the contactless plasma monitoring method to monitor the plasma state while maintaining plasma stability.

Hereinafter, an example of the present disclosure will be described in detail. However, the examples as described below are only some embodiments of the present disclosure, and the scope of the present disclosure is not limited to the following examples.

### Manufacture of Contactless Plasma Monitoring Device

An RF sensor is positioned such that the RF sensor may be positioned on top of the antenna of the particular inductively coupled plasma generation apparatus. The inductively coupled plasma generation apparatus includes a spiral-shaped antenna, wherein the RF sensors are arranged in a radial direction so as to be positioned at points 40, 88, 120, 152, 180, and 200 mm spaced from the center of the spiral, respectively, and the plane defined by the RF sensor is oriented to be perpendicular to the plane defined by the spiral. The induced electromotive force induced in each RF sensor was measured based on the time, and the function of the induced electromotive force based on the time was subjected to Fourier transform, and then the Fourier transform result is applied to a computing device equipped with software capable of deriving the amplitude value of the n-th harmonic. Accordingly, the contactless plasma monitoring device according to an embodiment of the present disclosure was manufactured.

### Calibration and Measurement of Contactless Plasma Monitoring Device

Nitrogen gas was charged into the inductively coupled plasma generation apparatus, and the inductively coupled plasma generation apparatus operated at an operating pressure of 10, 20, and 30 mTorr. The power applied to the antenna was set to 400, 600, and 800 W. A probe capable of measuring the electron density of plasma was previously inserted into the inductively coupled plasma generation apparatus, and the correlation between the electron density of plasma as measured by the probe and the amplitude value of the n-th harmonic derived by the non-contact plasma monitoring device was analyzed.

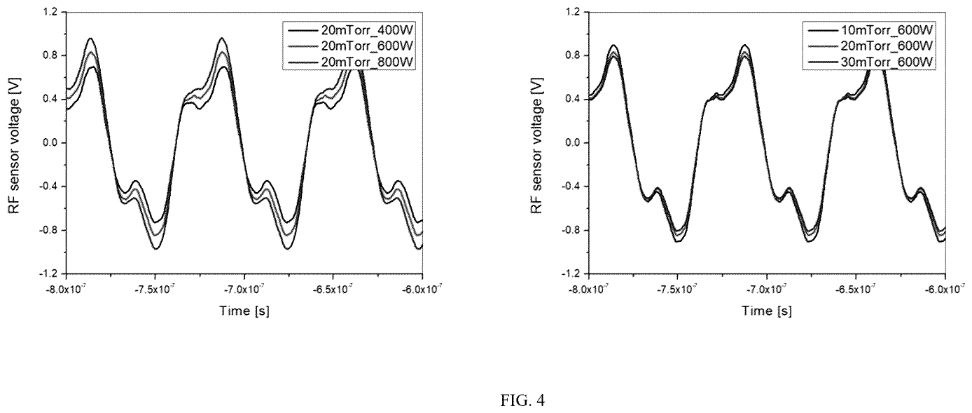

FIG. 4 is a graph showing a function based on the time of the induced electromotive force as recorded. The left side of FIG. 4 refers to an experimental result obtained by fixing the operating pressure to 20 mTorr, and the right side of FIG. 4 refers to an experimental result obtained by fixing the applied power to 600 W.

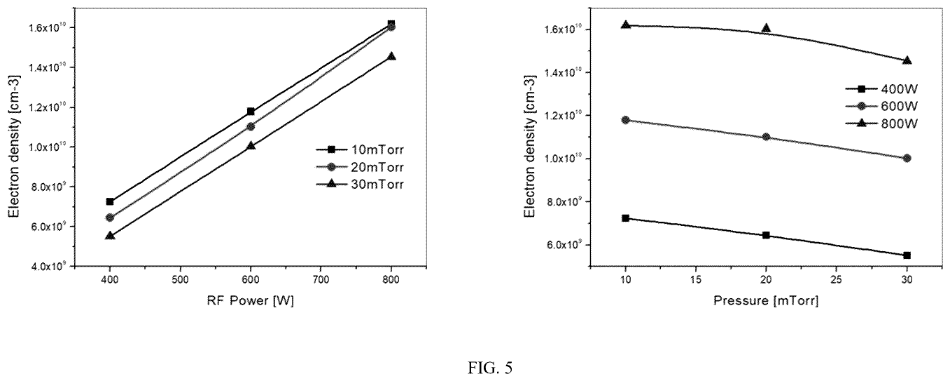

In the above operation of the apparatus, the probe simultaneously measured the electron density. FIG. 5 is a graph showing the results.

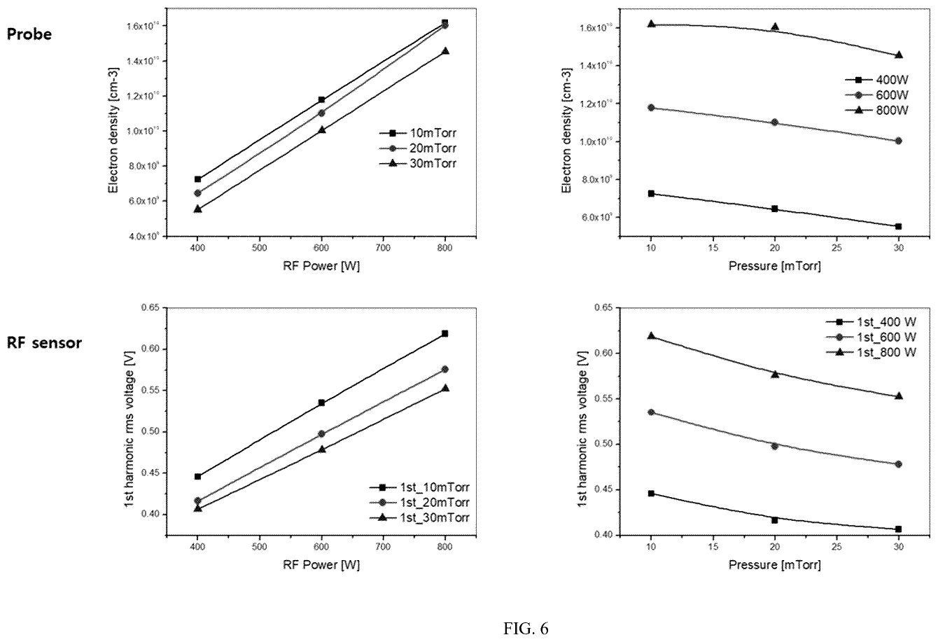

The amplitude value of the first harmonic and the electron density measured by the probe were compared with each other according to the operating conditions of the plasma generator. FIG. 6 is a graph showing the results. Referring to FIG. 6, it may be identified that the electron density directly measured by the probe and the amplitude value of the first harmonic derived by the plasma monitoring device have similar tendencies.

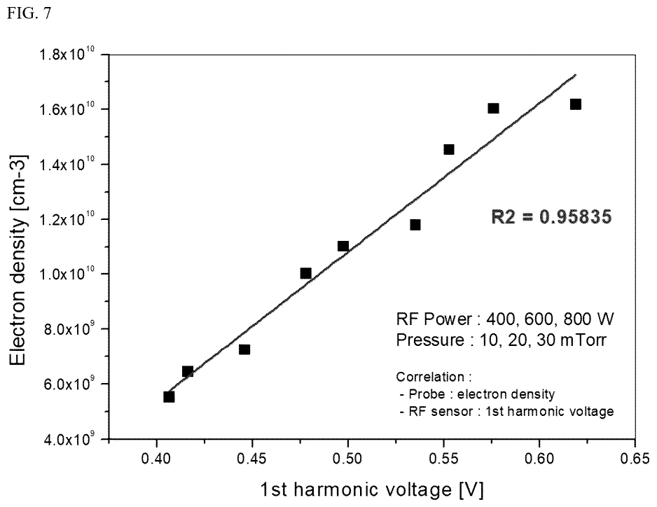

FIG. 7 is a result of comparing a direct measurement value through the probe and a derived value based on the amplitude value of the first harmonic with each other in order to quantitatively identify the similar tendency. Referring to FIG. 7, as a result of linearly fitting the point graphs of the two values, it may be identified that the R2 value shows a very high linear correlation of 0.95835. From this fact, it may be identified that the electron density and its distribution in the inductively coupled plasma device may be derived based on the amplitude value of the first harmonic without the direct measurement through the probe.

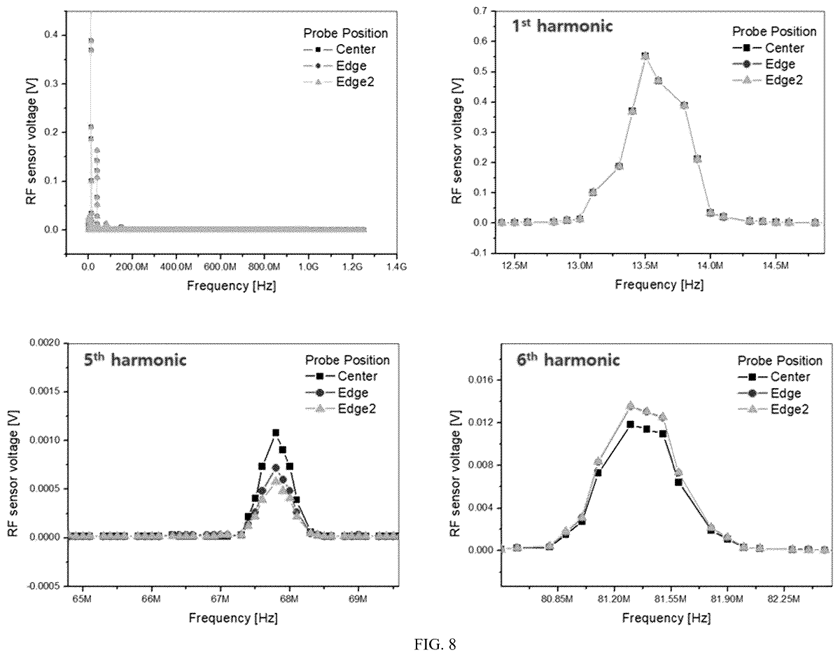

FIG. 8 is a graph showing a change in an amplitude value of the n-th harmonic when the probe operates in the inductively coupled plasma generator. center means that the probe is located at the center of the plasma generator, and edge and edge2 mean that the probe is located at the end of the generator. Referring to FIG. 8, the amplitude value of the first harmonic does not change based on the change in the position of the probe, whereas each of the amplitude value of the 5th harmonic and the amplitude value of the 6th harmonic increases and then decreases, or decreases and then increases. From this fact, it may be identified that when each of the amplitude values of the 5th and 6th harmonics is considerably changed by a predetermined value or greater, this may act as a detection signal indicating that impurities are introduced into the plasma.

### Spatial Magnetic Field Distribution Simulation

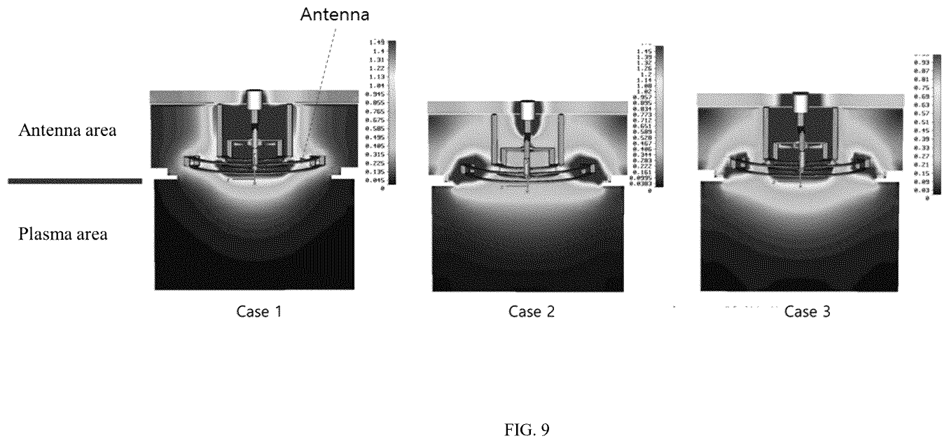

FIG. 9 is a result of simulating the spatial distribution of the magnetic field while controlling a current applied to an antenna on the plasma generator. Referring to FIG. 9, it may be identified that the distribution of the magnetic field around the antenna changes according to the change in the antenna operation condition. Therefore, based on this fact, when the RF sensor is located around the antenna, a plasma variable such as electron density or temperature may be finally derived by comparing the induced electromotive force value measured through the RF sensor with the magnetic field value obtained through simulation. Accordingly, it may be identified that the plasma state and uniformity may be monitored using the monitoring device and the RF sensor disposed outside the plasma generator.

Although described above with reference to preferred embodiments of the present disclosure, those skilled in the art will understand that the present disclosure may be variously modified and changed within the scope not departing from the spirit and scope of the present disclosure described in the following claims.

1. A contactless plasma monitoring method comprising:
a first step of positioning one or more RF sensors outside an ICP (Inductively Coupled Plasma) generator including an antenna, and of measuring an induced electromotive force induced in the RF sensor by the antenna as a function based on a time;
a second step of performing a Fourier transform on the function based on the time of the induced electromotive force and derive an amplitude value of an n-th harmonic from the Fourier transform result; and
a third step of deriving a state of plasma in the plasma generator based on the amplitude value of the n-th harmonic,
wherein n is a natural number of 1 or larger.

2. The contactless plasma monitoring method of claim 1, wherein the antenna is formed on at least one plane of the inductively coupled plasma generator,
wherein each of the RF sensors is positioned outside the antenna.

3. The contactless plasma monitoring method of claim 1, wherein n is 1,
wherein in the third step, a linear proportional relationship between the plasma electron density directly measured inside the plasma generator and the amplitude value is derived, and then an unknown plasma electron density is derived from an amplitude value measurement result based on the linear proportional relationship.

4. The contactless plasma monitoring method of claim 3, wherein in the first step, two or more RF sensors are positioned,
wherein in the third step, a distribution of unknown plasma electron density is derived based on a deriving result of the plasma electron density from each of the RF sensors.

5. The contactless plasma monitoring method of claim 2, wherein the third step includes determining whether impurities are introduced into the plasma, based on whether the amplitude value of the n-th harmonic is changed by a predetermined value or greater.

6. The contactless plasma monitoring method of claim 5, wherein n is 5 or 6.

7. A contactless plasma monitoring device comprising:
a sensor unit including: at least one RF sensor; and a recording unit configured to measure an induced electromotive force induced in each of the RF sensors and record the measured induced electromotive force as a function based on a time; and
a monitor unit including: a computation unit configured to perform the Fourier transform on the recorded function based on the time of the induced electromotive force; and
an output unit configured to derive a plasma state from an amplitude value of an n-th harmonic based on the Fourier-transform result of the computation unit,
wherein n is a natural number of 1 or greater.

8. The contactless plasma monitoring device of claim 7, wherein the contactless plasma monitoring device monitors plasma in an inductively coupled plasma generator in which an antenna is formed on at least one plane of the inductively coupled plasma generator,
wherein each of the RF sensors is positioned outside the antenna.

9. The contactless plasma monitoring device of claim 7, wherein n is 1,
wherein the output unit is configured to derives a linear proportional relationship between a plasma electron density directly measured inside the plasma generator and the amplitude value, and then to derive an unknown plasma electron density from an amplitude value measurement result based on the linear proportional relationship.

10. The contactless plasma monitoring device of claim 9, wherein the sensor unit includes two or more RF sensors,
wherein the output unit is configured to by derive the plasma electron density from each of the RF sensors and to derive an unknown plasma electron density distribution based on the derived plasma electron density.

11. The contactless plasma monitoring device of claim 8, wherein the output unit is configured to determine whether impurities are introduced into the plasma, based on whether the amplitude value of the n-th harmonic is changed by a predetermined value or greater.

12. The contactless plasma monitoring device of claim 11, wherein n is 5 or 6,
